(19) United States
(12) Patent Application Publication
(10) Pub. No.: US 2026/0307491 A1
(43) Pub. Date: Oct. 8, 2026

(54) DETECTION AND REMEDIATION OF LIQUID INTRUSION IN VEHICLE BATTERY PACKS

(71) Applicant: GM GLOBAL TECHNOLOGY OPERATIONS LLC, Detroit, MI (US)

(72) Inventors: Harmanpreet Singh BAINS, Rochester Hills, MI (US); Bryan Paul Jagielo, Linden, MI (US); Allison Laura Colarusso, Clawson, MI (US); Andrea Lee Capito, Redford, MI (US); Peyton Philip Huene, Novi, MI (US); Thomas Dougan, Brighton, MI (US)

(21) Appl. No.: 19/098,570

(22) Filed: Apr. 2, 2025

(51) Int. Cl. B60L 3/00; B60L 50/60; G01R 31/371; G01R 31/3835; G01R 31/389

(52) U.S. Cl. CPC B60L 3/0046; B60L 50/60; G01R 31/371; G01R 31/3835; G01R 31/389; B60L 2240/54

(57) ABSTRACT

A system includes a battery pack, a sensor configured to sense a midpack voltage of the battery pack, and a control module. The control module is configured to determine an isolation resistance of the battery pack based on the midpack voltage, monitor characteristics associated with the battery pack and indicative of liquid intrusion inside the battery pack, set one or more flags based on the monitored characteristics, identify a severity level of a plurality of severity levels for liquid intrusion inside the battery pack based on which one or more of the characteristics caused the one or more flags to be set, and select at least one remedial action of a plurality of remedial actions in response to the identified severity level for remediating liquid intrusion inside the battery pack. Other example systems and methods are also disclosed.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to detection and remediation of liquid intrusion in vehicle battery packs.

Electric vehicles, such as battery electric vehicles, hybrid vehicles, and/or fuel cell vehicles, include one or more electric machines and a battery system having one or more battery cells, modules, and/or packs. For example, the battery system may be a rechargeable energy storage system including one or more high voltage battery packs each having a collection of battery cells. Commonly, one or more of the battery packs in the rechargeable energy storage system are electrically isolated from components outside of the battery pack.

### SUMMARY

A system for detecting and remediating liquid intrusion inside a battery pack of a vehicle, includes a battery pack including a plurality of battery cells, a sensor configured to sense a midpack voltage of the battery pack, and a control module in communication with the one or more sensors. The control module is configured to determine an isolation resistance of the battery pack based on the midpack voltage, monitor characteristics associated with the battery pack and indicative of liquid intrusion inside the battery pack, the characteristics including a current value of the isolation resistance, a behavior of the midpack voltage over time, and a behavior of the isolation resistance over time, set one or more flags based on the monitored characteristics, identify a severity level of a plurality of severity levels for liquid intrusion inside the battery pack based on which one or more of the characteristics caused the one or more flags to be set, and select at least one remedial action of a plurality of remedial actions in response to the identified severity level for remediating liquid intrusion inside the battery pack.

In other features, the control module is configured to generate a control signal for implementing the at least one selected remedial action.

In other features, the plurality of severity levels include a first severity level corresponding to a severe state of liquid intrusion and a second severity level corresponding to a less severe state of liquid intrusion as compared to the first severity level.

In other features, the control module is configured to identify the first severity level for liquid intrusion inside the battery pack when the current value of the isolation resistance is less than a defined threshold.

In other features, the plurality of remedial actions include a set of urgent remedial actions and a set of non-urgent remedial actions, and the control module is configured to select at least one of the urgent remedial actions in response to identifying the first severity level.

In other features, the set of urgent remedial actions include changing a charge control setting for the battery pack, changing a chiller control setting for the vehicle, changing a power limit setting for the vehicle, changing a coolant pump control setting, setting a diagnostic trouble code (DTC), and providing an emergency driver notification.

In other features, the control module is configured to identify the second severity level for liquid intrusion inside the battery pack based on a change in the midpack voltage over time and a first threshold or a change in the isolation resistance over time and a second threshold.

In other features, the plurality of remedial actions include a set of urgent remedial actions and a set of non-urgent remedial actions, the control module is configured to select at least one of the non-urgent remedial actions in response to identifying the second severity level, and the set of non-urgent remedial actions include changing a state-of-charge limit for the battery pack, changing a power limit setting for the vehicle, setting a diagnostic trouble code (DTC), and providing a driver notification.

In other features, the plurality of severity levels include a first severity level corresponding to a severe state of liquid intrusion and a second severity level corresponding to a less severe state of liquid intrusion as compared to the first severity level, the one or more flags include at least a first flag set based on the current value of the isolation resistance and a second flag set based on the behavior of the midpack voltage over time or the behavior of the isolation resistance over time, and the identified severity level is the first severity level.

In other features, the plurality of severity levels include a first severity level corresponding to a severe state of liquid intrusion and a second severity level corresponding to a less severe state of liquid intrusion as compared to the first severity level, the one or more flags include at least a first flag set based on the behavior of the midpack voltage over time and a second flag set based on the behavior of the isolation resistance over time, and the identified severity level is the second severity level.

A method for detecting and remediating liquid intrusion inside a battery pack of a vehicle, includes receiving, from a voltage sensor, a midpack voltage of the battery pack, determining an isolation resistance of the battery pack based on the midpack voltage, monitoring characteristics associated with the battery pack and indicative of liquid intrusion inside the battery pack, the characteristics including a current value of the isolation resistance, a behavior of the midpack voltage over time, and a behavior of the isolation resistance over time, setting one or more flags based on the monitored characteristics, identifying a severity level of a plurality of severity levels for liquid intrusion inside the battery pack based on which one or more of the characteristics caused the one or more flags to be set, and selecting at least one remedial action of a plurality of remedial actions in response to the identified severity level for remediating liquid intrusion inside the battery pack.

In other features, the method further includes generating a control signal for implementing the at least one selected remedial action.

In other features, the plurality of severity levels include a first severity level corresponding to a severe state of liquid intrusion and a second severity level corresponding to a less severe state of liquid intrusion as compared to the first severity level, the one or more flags include at least a first flag set based on the current value of the isolation resistance and a second flag set based on the behavior of the midpack voltage over time or the behavior of the isolation resistance over time, and identifying the severity level for liquid intrusion inside the battery pack includes identifying the first severity level.

In other features, the plurality of severity levels include a first severity level corresponding to a severe state of liquid intrusion and a second severity level corresponding to a less severe state of liquid intrusion as compared to the first severity level, the one or more flags include at least a first flag set based on the behavior of the midpack voltage over time and a second flag set based on the behavior of the isolation resistance over time, and identifying the severity level for liquid intrusion inside the battery pack includes identifying the second severity level.

In other features, the plurality of severity levels include a first severity level corresponding to a severe state of liquid intrusion and a second severity level corresponding to a less severe state of liquid intrusion as compared to the first severity level and the plurality of remedial actions include a set of urgent remedial actions and a set of non-urgent remedial actions.

In other features, identifying the severity level for liquid intrusion inside the battery pack includes identifying the first severity level when the current value of the isolation resistance is less than a defined threshold, selecting the at least one remedial action includes selecting at least one of the urgent remedial actions in response to identifying the first severity level, and the set of urgent remedial actions include changing a charge control setting for the battery pack, changing a chiller control setting for the vehicle, changing a power limit setting for the vehicle, changing a coolant pump control setting, setting a diagnostic trouble code (DTC), and providing an emergency driver notification.

In other features, identifying the severity level for liquid intrusion inside the battery pack includes identifying the second severity level based on a change in the midpack voltage over time and a first threshold or a change in the isolation resistance over time and a second threshold, and selecting the at least one remedial action includes selecting at least one of the non-urgent remedial actions in response to identifying the second severity level.

In other features, the set of non-urgent remedial actions include changing a state-of-charge limit for the battery pack, changing a power limit setting for the vehicle, setting a diagnostic trouble code (DTC), and providing a driver notification.

A non-transitory computer readable medium including instructions that, when executed by a control module, are configured to detect and remediate liquid intrusion inside a battery pack of a vehicle by determining an isolation resistance of the battery pack based on a sensed midpack voltage, monitoring characteristics associated with the battery pack and indicative of liquid intrusion inside the battery pack, the characteristics including a current value of the isolation resistance, a behavior of the midpack voltage over time, and a behavior of the isolation resistance over time, setting one or more flags based on the monitored characteristics, identifying a severity level of a plurality of severity levels for liquid intrusion inside the battery pack based on which one or more of the characteristics caused the one or more flags to be set, and selecting at least one remedial action of a plurality of remedial actions in response to the identified severity level for remediating liquid intrusion inside the battery pack.

In other features, the non-transitory computer readable medium includes instructions for generating a control signal for implementing the at least one selected remedial action.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a block diagram of an example system for detecting and remediating liquid intrusion inside a battery pack, according to the present disclosure;

FIG. 2 is a vehicle including portions of the system of FIG. 1, according to the present disclosure;

FIG. 3 is a block diagram of an example battery pack of the system in FIG. 1, according to the present disclosure;

FIG. 4 is a block diagram of an example cell group of the battery pack in FIG. 3, according to the present disclosure;

FIG. 5 is a block diagram of another example system for detecting and remediating liquid intrusion inside a battery pack, according to the present disclosure; and

FIGS. 6-7 are flowcharts of example control processes for detecting and remediating liquid intrusion inside a battery pack, according to the present disclosure.

In the drawings, reference numbers may be reused to identify similar and/or identical elements.

### DETAILED DESCRIPTION

An electric vehicle (EV), such as a battery electric vehicle, a hybrid vehicle, and/or a fuel cell vehicle, often relies on a rechargeable energy storage system (RESS) for storing and supplying power to propel the vehicle. In such examples, the RESS includes one or more high voltage battery packs each having a collection of battery cells. In some examples, battery cells may be located in modules in each battery pack. In the RESS, one or more of the battery packs are electrically isolated from components outside of the battery packs, such as the vehicle’s chassis. With this configuration, the RESS or components thereof are coupled to high voltage components without being grounded to, for example, the vehicle’s chassis. In other words, the RESS or components thereof are electrically isolated from the vehicle’s chassis.

Sometimes, conditions arise in the RESS and/or other high voltage components causing a loss of isolation, such as liquid intrusion inside the high voltage battery packs. In such examples, liquid may include water, coolant, electrolyte, etc. In some examples, a vehicle diagnostic monitor may detect shock hazard conditions by focusing on a loss of isolation (e.g., the reduction of isolation resistance). However, such techniques are often inefficient in detecting and remediating liquid intrusions inside the high voltage battery packs. For example, while a shock hazard condition may be detected by the vehicle diagnostic monitor, the detection occurs late and/or without advanced warning and does not trigger remedial measures for mitigating the issue. Additionally, a conventional vehicle diagnostic monitor operates only on one threshold value and does not have any escalation based on the severity of the risk.

The systems and methods according to the present disclosure provide solutions for detecting liquid intrusion in a high voltage battery pack of an EV from a thermal runaway point of view and take appropriate remedial actions based on the detection. For example, the systems and methods may monitor changes in various sensors/indicators (e.g., voltage sensor values, communication fault, thermal management system behaviors, etc.), set one or more flags based on the monitored changes indicative of liquid detection or other indicators of liquid in the high voltage battery pack, and then perform sensor fusion to identify or otherwise estimate a severity level. Then, based on the severity level, appropriate remedial actions can be taken to mitigate the effects of liquid intrusion. With this approach, the detection of liquid intrusion in the high voltage battery pack may occur well in advance (e.g., up to two weeks prior, etc.) of a conventional vehicle diagnostic monitor detecting a shock hazard condition. This, in turn, would provide ample time to take appropriate remedial actions and/or replace the battery pack (if necessary), thereby mitigating the risk of a severe fire hazard and/or a shock hazard resulting from the liquid intrusion. As a result, vehicle and user (e.g., drivers, passengers, bystanders, etc.) safety is enhanced. Additionally, implementation of this approach may utilize existing vehicle sensors/indicators and therefore substantial minimize hardware and vehicle production costs. Further, this approach allows for the monitoring and detection of liquid to be less localized to a specific part in the RESS as compared to the conventional vehicle diagnostic monitor and can even detect liquid which is moving around the pack as the vehicle moves.

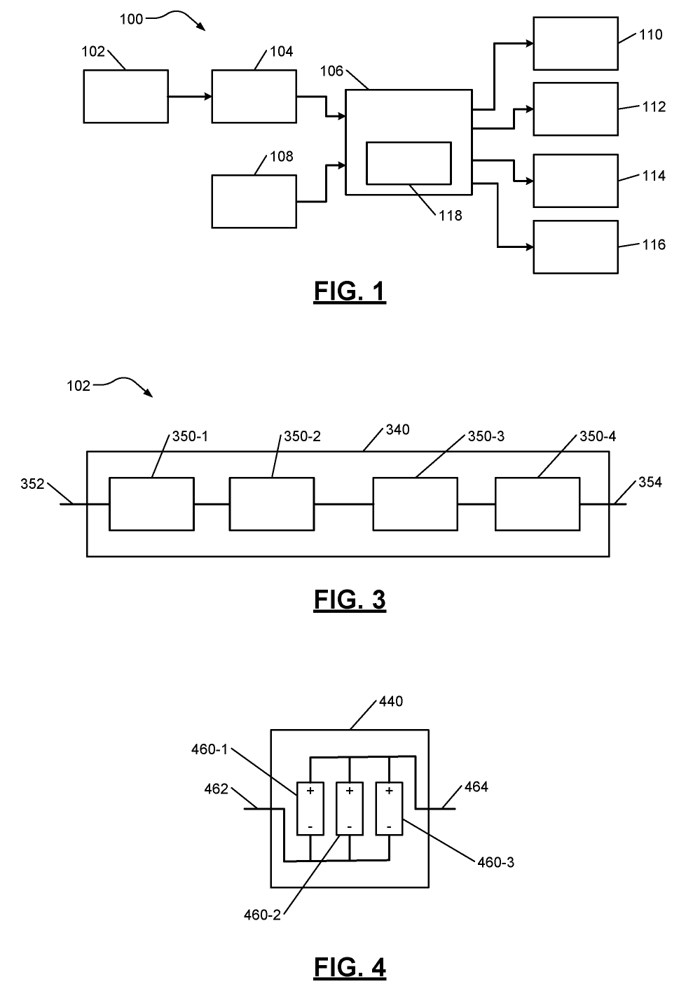

Referring now to FIG. 1, a block diagram of an example system 100 is presented for detecting and remediating liquid intrusion inside a battery pack. As shown in FIG. 1, the system 100 generally includes a battery pack 102, one or more voltage sensors 104 for sensing one or more voltages of the battery pack 102, and a control module 106. In various embodiments, the system 100 may further include one or more additional sensors 108, a display module 110, a vehicle control module 112, a battery charge control module 114, and a chiller control module 116.

Although FIG. 1 illustrates the system 100 as including specific dedicated modules, it should be appreciated that one or more other modules may be employed if desired. For example, any combination of the modules (e.g., the control module 106, the display module 110, the vehicle control module 112, the battery charge control module 114, the chiller control module 116, etc.) and/or the functionality thereof may be integrated into a single module or multiple different modules. Additionally, while the system 100 is shown as including one battery pack 102, it should be appreciated that the system 100 may include multiple battery packs. Regardless of the number of battery packs in the system 100, the single battery pack or multiple battery packs may be part of a RESS.

In various embodiments, the modules and sensors of the system 100 may be in communication with each other and may share parameters via a network, such as a controller area network (CAN). In such examples, the parameters may be shared via one or more data buses of the network. As such, various parameters may be made available by a given module and/or sensor to other modules and/or sensors via the network.

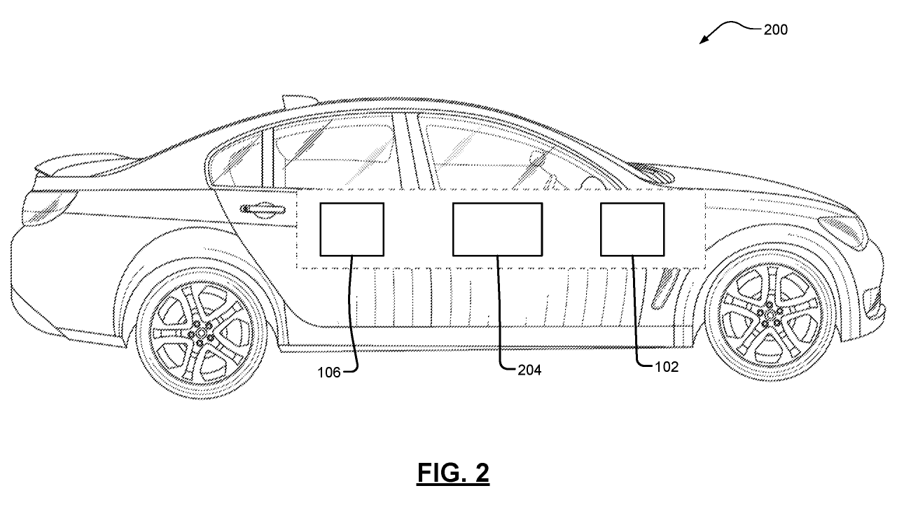

The system 100 of FIG. 1 may be employable in any suitable implementation in which one or more high voltage battery packs are employed. For example, the system 100 may be employed in vehicles implementations or non-vehicles implementations. Further, if the system 100 may be employed in a vehicle implementation, the system 100 may be positioned in a vehicle. With respect to vehicles implementations, the system 100 may be a part of any suitable vehicle having a RESS including one or more high voltage battery packs for storing and supply power to propelling the vehicle. In such examples, the vehicle may be an electric vehicle, such as a pure electric vehicle, a hybrid electric vehicle, etc. Additionally, the system 100 may be applicable to an autonomous vehicle, a semi-autonomous vehicle, etc. As one example, FIG. 2 depicts a vehicle 200 including the battery pack 102 of FIG. 1, sensor(s) 204, and the control module 106 of FIG. 1. In this example, the sensor(s) 204 may include any one or more of the sensors 104, 108 of FIG. 1.

With continued reference to FIG. 1, the battery pack 102 generally includes multiple battery cells. In such examples, each battery cell may be capable of storing and supplying power. In various embodiments, a defined collection of battery cells may form a cell group or cell module, each of which may be selectively removed or replaced with another cell group. For example, FIG. 3 depicts one example of the battery pack 102 of FIG. 1. As shown in FIG. 3, the battery pack 102 includes a battery enclosure 340, cell groups (indicated generally by 350) positioned within the battery enclosure 340, and battery leads 352, 354 coupled to the cell groups. In such examples, the cell groups include any suitable number of cell groups. For instance, in FIG. 3, the battery pack 102 includes four cell groups 350-1, 350-2, 350-3, 350-4. In other examples, the battery pack 102 may include one includes one cell group, two cell groups, five cell groups, ten cell groups, sixteen cell groups, twenty-four cell groups, etc. Regardless of the number of cell groups, the battery leads 352, 354 electrically connect the battery pack 102 (e.g., the cell groups 350-1, 350-2, 350-3, 350-4) to an output (e.g., a load), an input (e.g., a power supply), etc.

In various embodiments, the battery pack 102 of FIG. 1 may include battery cells or cell groups coupled in series and/or parallel configurations to obtain different high voltages. For example, the battery cells and/or cell groups may be coupled in manner to provide a high voltage, such as a suitable voltage over 50 volts (e.g., 100 volts, 400 volts, 800 volts, etc.). For instance, and shown in FIG. 2, the cell groups 350-1, 350-2, 350-3, 350-4 are coupled series.

Additionally, in some examples, the battery cells in any one of the cell groups may have a series and/or parallel configuration. For example, FIG. 4 depicts one example of the cell group 350-1 of FIG. 3. As shown in FIG. 4, the cell group 350-1 includes an enclosure 440, battery cells (indicated generally by 460) positioned within the enclosure 440, and leads 462, 464 coupled to the battery cells. In this example, the cell group 350-1 includes three battery cells 460-1, 460-2, 460-3 coupled in parallel. In other examples, the cell group 350-1 may include more or less battery cells (e.g., two battery cells, eight battery cells, twelve battery cells, thirty-six battery cells, forty-eight battery cells, ninety-six battery cells, etc.) coupled in series, a series/parallel configuration, etc. In the example of FIG. 4, the lead 462 may be equivalent to the battery leads 352 of FIG. 3 and the lead 464 may be coupled to the cell group 350-2 of FIG. 3.

In the example of FIG. 1, the voltage sensor(s) 104 may be any suitable type of sensor for detecting voltages associated with the battery pack 102. For example, the voltage sensor(s) 104 may sense an output voltage of the battery cells in the battery pack 102 (e.g., a pack voltage), a negative midpack voltage of the battery pack 102, and/or a positive midpack voltage of the battery pack 102. In such examples, the control module 106 (or another suitable control module) may cycle an isolation switch to sense the negative midpack voltage and/or the positive midpack voltage. For instance, the negative midpack voltage may be a chassis voltage in the vehicle 200 of FIG. 2, represented by the voltage between the negative rail and the chassis ground. In this example, the voltage sensor(s) 104 may provide one or more signals (e.g. voltage signals) to the control module 106 representing voltage values of the battery pack 102. In various embodiments, the voltage sensor(s) 104 may be a voltage divider including multiple resistors and/or another suitable type of sensor.

With continued reference to FIG. 1, the control module 106 may generally detect liquid intrusion the battery pack 102 from a thermal runaway point of view and take appropriate remedial actions based on the detection. For example, and as further explained below, the control module 106 may utilize various indictors, such as chassis voltage indicators, loss of communication indicators and thermal management indicators to detect liquid in battery pack 102. Then, the control module 106 can monitor the indicators (e.g., inputs provided by sensors, etc.) to generate fault flags and estimate the severity to the system 100. Then, based on the severity, control module 106 can generate different customer facing remedial actions (e.g., long term, non-urgent remedial actions or urgent remedial actions).

Specially, in FIG. 1, the control module 106 generally monitors for different indicators for liquid intrusion inside the battery pack 102. For example, and as shown in FIG. 1, the control module 106 may receive a midpack voltage (e.g., a negative midpack voltage, etc.) and an output voltage of the battery pack 102 from the voltage sensor(s) 104. Then, the control module 106 can determine an isolation resistance of the battery pack 102 based on the received midpack voltage and the output voltage.

In the example of FIG. 1, the midpack voltage, the isolation resistance, and other possible characteristics associated with the battery pack 102 may be indicators monitors by the control module 106 to detect liquid intrusion inside the battery pack 102. In other words, the monitored characteristics may be indicative of liquid intrusion inside the battery pack 102. In various embodiments, the monitored characteristics may include a current value of the isolation resistance, a behavior of the midpack voltage over time, a behavior of the isolation resistance over time, a loss of communication with the battery pack 102 (or more generally a RESS including the battery pack 102), a status of a battery contactor to check for positive/negative stuck contactor faults, a status of an isolation switch, inputs from humidity sensors, a status of dissolvable plugs (e.g., seals, etc.) in the battery pack 102, thermal management indicators (e.g., increased temperature, increased heat discharge, etc.) suggestive of a short, etc.

Then, the control module 106 may set one or more flags based on the monitored characteristics. In such examples, the control module 106 may set a flag for each monitored characteristic depending on if that monitored characteristic meets a threshold. As such, in some examples, the control module 106 may not set a flag if the monitored characteristics are within defined thresholds, set one flag if only one monitored characteristic meets its corresponding defined threshold, or set multiple flags if multiple monitored characteristics meet their corresponding defined thresholds.

For example, the control module 106 may set one flag based on a current value of the isolation resistance. In such examples, the control module 106 may implement a diagnostic algorithm to detect liquid in the battery pack 102 by characterizing the system response. This diagnostic algorithm may use, for example, existing active isolation hardware to calculate a time constant of the system (e.g., how quickly a circuit can change its voltage) by analyzing the midpack voltage (e.g., the negative midpack voltage). In such examples, the time constant is a parameter characterizing the system response and provides a correlation to the isolation resistance. For example, a larger time constant indicates a slower response time due to a higher isolation resistance and a smaller time constant indicates a faster response time due to a lower isolation resistance. In such examples, the control module 106 sets a flag if the calculated time constant falls outside of a defined threshold. In other words, if the current value of the isolation resistance (or the calculated time constant) is below a defined threshold (e.g., indicating a loss of isolation), the control module 106 sets a flag. In such examples, the defined threshold may be 1.8 megaohms (MΩ), 2 MΩ, 2.2 MΩ, or another suitable value.

Additionally, the control module 106 may set one or more other flags based on the behavior of the isolation resistance over time. In such examples, the control module 106 may implement another diagnostic algorithm to detect liquid in the battery pack 102 by monitoring for erratic behavior of the system time constant across multiple time scales. In this example, the diagnostic algorithm take as inputs the time constant and monitors for erratic behavior both in the short term (e.g., on the order of minutes) and the long term (e.g., on the order of days). Then, based on the time scale at which erraticness is detected by the diagnostic algorithm, the control module 106 may set one or multiple different flags based on the severity of the fault. In other words, due to the correlation between the time constant and the isolation resistance, the control module 106 may set one or more other flags based on the erratic behavior of the isolation resistance across multiple time scales. In such examples, the control module 106 may set one or more flags based on an erratic change (e.g., a sudden change, a large change, etc.) in the isolation resistance and an expected behavior of the isolation resistance (or a defined threshold).

Further, the control module 106 may set another flag based on the behavior of the midpack voltage (e.g., the negative midpack voltage) received from the voltage sensor(s) 104 over time. For instance, the control module 106 may implement another diagnostic algorithm to detect liquid in the battery pack 102 by monitoring for erratic behavior of an isolation circuit in the vehicle 200 of FIG. 2. Generally, the negative midpack voltage toggles in a predictable, monotonic way. However, when the negative midpack voltage is detected to have strayed too far from its expected behavior, the diagnostic algorithm detects a fault. In such example, the control module 106 may set one or more flags based on the behavior of the midpack voltage and an expected behavior of the midpack voltage (or a defined threshold). For instance, a flag may be set based a change in the midpack voltage over time diverting from its expected behavior, such as a magnitude of the midpack voltage changing in an unexpected direction (e.g., the negative midpack voltage is toggling in an unexpected direction), etc.

In other examples, the control module 106 may implement one or more other diagnostic algorithms to detect liquid in the battery pack 102 by monitoring other characteristics or indicators in the system 100 and then set flags based on the monitoring. In such examples, the control module 106 may receive the characteristics/indicators as inputs from the sensor(s) 108 in FIG. 1. For example, the control module 106 may receive sensor inputs relating to a loss of communication, a status of a battery contactor, a status of an isolation switch, inputs from humidity sensors, a status of dissolvable plugs, thermal management indicators (e.g., increased temperature, increased heat discharge, etc.), etc. and then set one or more flags based on the such inputs.

In various embodiments, the control module 106 then identifies a severity level for liquid intrusion inside the battery pack 102. In such examples, the severity level identified may be one of multiple possible severity levels. For example, the severity levels may include a high severity level corresponding to a severe state of liquid intrusion and a low severity level corresponding to a less severe state of liquid intrusion as compared to the high severity level. In other examples, the severity levels may include intermedial levels between the high severity level and the low severity level.

In the example of FIG. 1, the control module 106 may identify the severity level based on which one or more of the characteristics caused the one or more flags to be set. With this approach, the severity level is identified by the control module 106 based on which flag is or flags are set and not values associated with such flags. For example, if only one flag is set, the control module 106 may identify a severity level based the characteristic causing that flag. In other examples, if multiple flags are set, the control module 106 may implement a fusion algorithm to identify a severity level based on the characteristics causing the multiple flags. In such examples, some characteristics may automatically cause the severity level to rise to the high severity level regardless of whether no other flags are set or of multiple other flags being set. In such examples, a single flag set based on a particular characteristic or multiple flags with this single flag can cause the control module 106 to identify the severity level as high. In other examples, multiple flags set based on multiple characteristics may cause the control module 106 to identify the severity level as low if the characteristics are indicative of less severe liquid intrusion.

For example, the control module 106 may identify the severity level as a high severity level when the basis for setting a flag is due to the current value of the isolation resistance (or the calculated time constant) being below a defined threshold. In such examples, the control module 106 may make this severity level identification if this flag is only set flag or is one of multiple set flags. In other words, the isolation resistance falling below a defined threshold is a critical characteristic, in which a flag set due to this characteristic causes the control module 106 to identify the severity level as high regardless of whether other flags (or no other flags) are set.

In other examples, the control module 106 may identify the severity level as a low or lower severity level when the basis for setting a flag is due to the erratic behavior of the midpack voltage over time or the behavior of the isolation resistance over time. For example, if two flags are set based on a change in the midpack voltage over time and a defined threshold and a change in the isolation resistance over time and another defined threshold, the control module 106 may identify the severity level as a low severity level.

Then, the control module 106 may select at least one remedial action in response to the identified severity level for remediating liquid intrusion inside the battery pack 102. In such examples, the remedial action(s) selected may be one or more of multiple remedial actions available. For example, the remedial actions may include a set of urgent remedial actions corresponding to different actions for a high or higher severity level, and a set of less urgent or non-urgent remedial actions corresponding to different actions for a low or lower severity level. In such examples, the urgent remedial actions may be critical in that the severity of the liquid intrusion may lead to a loss of isolation with respect to the battery pack 102 and in turn an elevated risk of shock and/or fire. As such, the control module 106 may select one or more urgent remedial actions in response to the severity level being identified as a high severity level. In contrast, the less urgent or non-urgent remedial actions may be less critical in that the severity of the liquid intrusion may possibly lead to a loss of isolation in the future (e.g., a week, two weeks, a month, etc. and in turn a future elevated risk of shock and/or fire if action is not taken. As such, the control module 106 may select one or more non-urgent remedial actions in response to the severity level being identified as a low severity level.

In various embodiments, the urgent remedial actions and the non-urgent remedial actions may include any suitable action for remediating liquid intrusion. For example, and as further explained below, the urgent remedial actions may include changing a charge control setting for the battery pack 102, changing a chiller control setting for the vehicle 200, changing a power limit setting for the vehicle 200, changing a coolant pump control setting, setting a diagnostic trouble code (DTC), providing an emergency driver notification, etc. Similarly, the non-urgent remedial actions may include changing a state-of-charge limit for the battery pack 102, changing a power limit setting for the vehicle 200, setting a DTC, providing a driver notification, etc.

In the example of FIG. 1, the control module 106 may select the appropriate remedial action(s) based on the identified severity level, along with other parameters associated with the battery pack 102 and/or other battery packs in the vehicle (e.g., the vehicle 200 of FIG. 2), parameters associated with the vehicle, etc. For example, the control module 106 may include one or more lookup tables stored in a memory circuit 118. In such examples, the memory circuit 118 may be internal to the control module 106 as shown in FIG. 1 or external to but accessible by the control module 106. With this approach, configuration parameters for the battery pack 102, the vehicle, etc. may provide different available remedial action(s). For instance, depending on the make, model, trim package, etc. of the vehicle, some remedial action(s) may be unavailable. As one example, a particular vehicle may not include a chiller and therefore remedial action(s) for this vehicle may not include changing a chiller control setting for the vehicle 200.

In various embodiments, the selected remedial action(s) may be automatically implemented without need for user input. For example, in response to selected remedial action(s), the control module 106 may generate one or more control signals for implementing the remedial action(s). The control module 106 may then transmit the control signals to other appropriate modules for implementing the remedial action(s).

For instance, if the selected remedial action is providing a driver notification (e.g., an emergency driver notification, a conventional driver notification, etc.), the control module 106 may generate and transmit a control signal to the display module 110 causing the display module 110 to display the driver notification. In such examples, the driver notification may be a diver information center (DIC) message for reduced power, service high voltage (HV) system, etc.

Additionally, the control module 106 may generate and transmit a control signal to the vehicle control module 112 if, for example, the selected remedial action includes changing a power limit setting for the vehicle. For example, after receiving the control signal, the vehicle control module 112 may reduce propulsion power for the vehicle, cause the vehicle to stop or automatously pull over, etc. depending on whether the remedial action is urgent or non-urgent.

Further, the control module 106 may generate and transmit a control signal to the battery charge control module 114 if, for example, the selected remedial action includes changing a charge control setting for the battery pack 102. For example, after receiving the control signal, the battery charge control module 114 may reduce charging power provided to the battery pack 102, stop or prevent direct current fast charging (DCFC) of the battery pack 102, reduce a state-of-charge (SOC) limit for the battery pack 102, etc. depending on whether the remedial action is urgent or non-urgent.

Also, the control module 106 may generate and transmit a control signal to the chiller control module 116 if, for example, the selected remedial action includes changing a chiller control setting. For instance, after receiving the control signal, the chiller control module 116 may stop or prevent activation of a chiller request, stop coolant flow to the battery pack 102, etc.

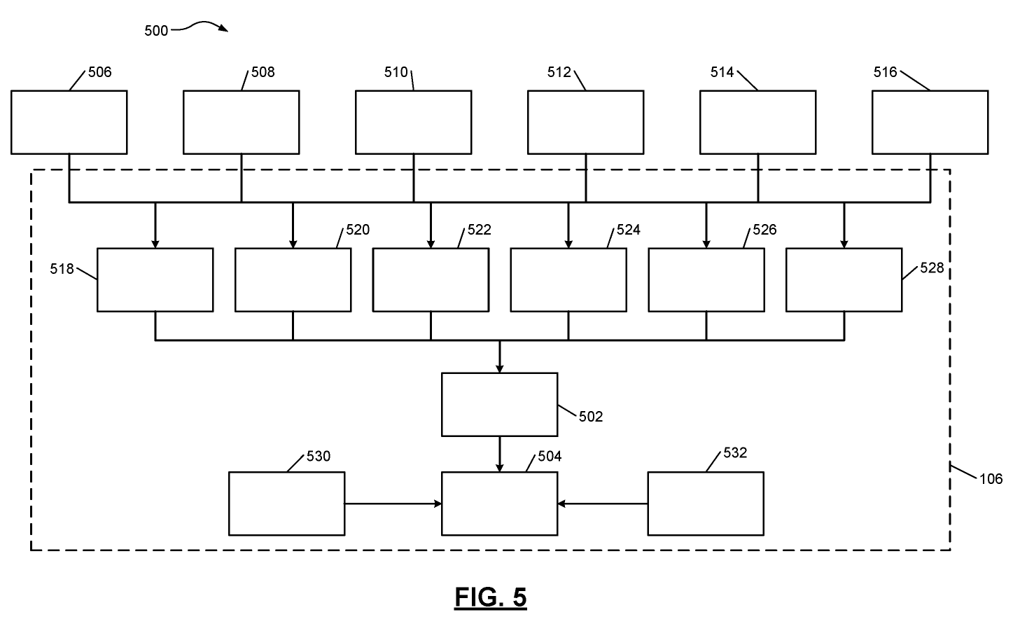

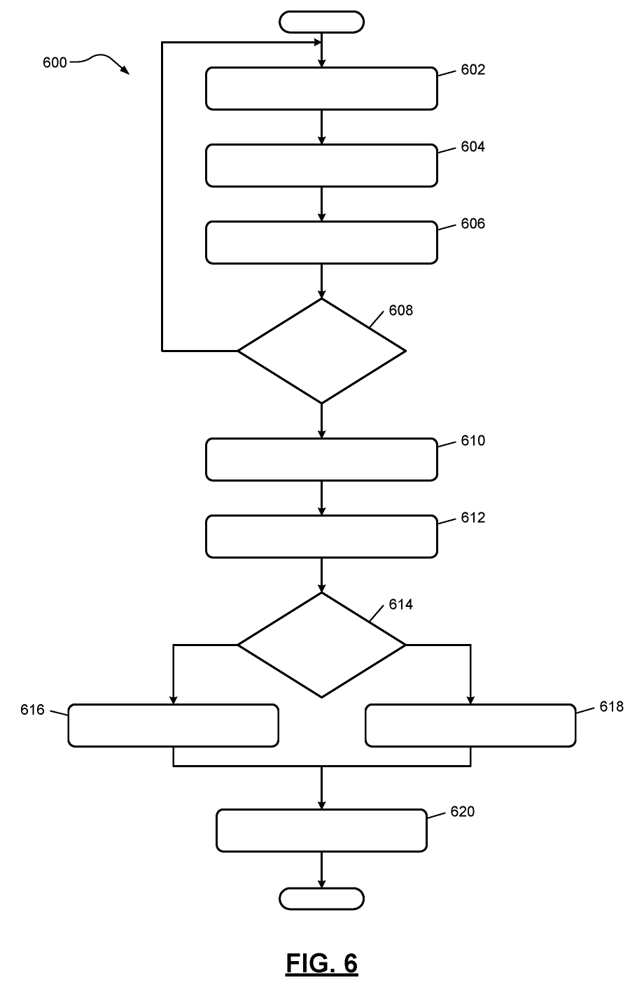

FIG. 5 depicts another example system 500 for detecting and remediating liquid intrusion inside a battery pack. The system 500 is generally similar to the system 100 of FIG. 1 with respect to its functions but includes specific control components for implementing the functions. For example, and as shown in FIG. 5, the system 500 includes multiple sensors, multiple monitors, a sensor fusion module 502, and a risk mitigation module 504. In this example, the monitors, the sensor fusion module 502, and the risk mitigation module 504 may be part of a control module, such as the control module 106 of FIG. 1.

In the example of FIG. 5, the sensors include a loss of communication sensor 506, contactor status sensor 508, an isolation switch sensor 510, a battery pack voltage sensor 512, a midpack voltage sensor 514, and a thermal management senor 516. In such examples, the battery pack voltage sensor 512 and the midpack voltage sensor 514 may correspond to the voltage sensor(s) 104 of FIG. 1, and the other sensors 506, 508, 510, 516 may correspond to the sensor(s) 108 in FIG. 1. The monitors of FIG. 5 include a loss of communication monitor 518, a midpack erratic voltage monitor 520, a reduced isolation monitor 522, an isolation resistance erratic monitor 524, a contactor monitor 526, and a humidity/dissolvable plug monitor 528.

In FIG. 5, the monitors may generate and set flags based on input from the sensors, as explained herein. For example, the reduced isolation monitor 522 may set a flag based on a current value of an isolation resistance (e.g., calculated based on the output voltage and the midpack voltage of the battery pack), as explained above. Additionally, the midpack erratic voltage monitor 520 and the isolation resistance erratic monitor 524 may set flags based on the behavior of the midpack voltage and the behavior of the isolation resistance, respectively, as explained above. Further, the loss of communication monitor 518, the contactor monitor 526, and the humidity/dissolvable plug monitor 528 may set flags based on the input from the loss of communication sensor 506, the contactor status sensor 508, the isolation switch sensor 510, the thermal management senor 516, etc.

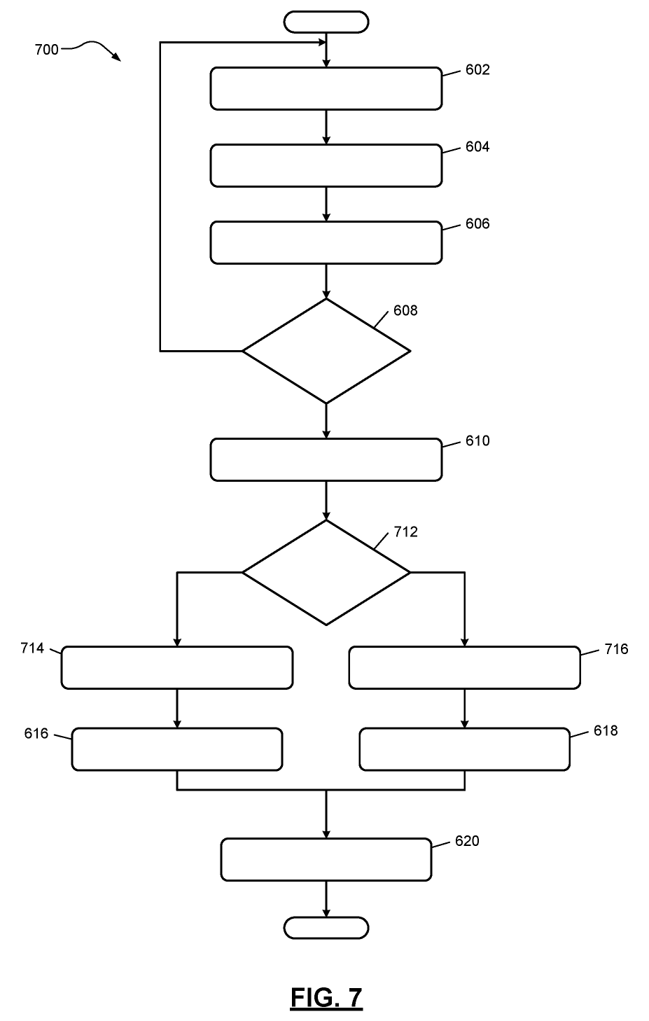

FIGS. 6-7 illustrate example control processes 600, 700 employable by the systems 100, 500 of FIGS. 1 and 5 for detecting and remediating liquid intrusion inside a battery pack, such as the battery pack 102. Although the example control processes 600, 700 are described in relation to the system 100 of FIG. 1 including the control module 106, any one of the control processes 600, 700 may be employable by another suitable system.

As shown in FIG. 6, the control process 600 begins by receiving a midpack voltage and an output voltage of a battery pack, such as the battery pack 102 of FIG. 1. For example, and as explained above, the control module 106 may receive signals indicating a negative midpack voltage and an output voltage of the battery pack 102 from the voltage sensor(s) 104. The control process 600 then proceeds to 604, where the control module 106 determines an isolation resistance of the battery pack based on the midpack voltage and the output voltage, as explained above. The control process 600 then proceeds to 606.

At 606, the control module 106 monitors characteristics associated with the battery pack that are indicative of liquid intrusion inside the battery pack. For example, and as explained above, the control module 106 may monitor a current value of the isolation resistance, a behavior of the midpack voltage over time, a behavior of the isolation resistance over time, etc. Then, at 608, the control module 106 determines whether any of the monitored characteristics is less than or greater than a corresponding defined threshold. If no, the control process 600 returns to 602 or another suitable step, such as 606. If yes at 608, the control process 600 proceeds to 610.

At 610, the control module 106 sets one or more flags based on the monitored characteristics. For example, and as explained above, the control module 106 may set a flag for each monitored characteristic depending on if that monitored characteristic meets a threshold. As such, the control module 106 may set one flag or multiple flags if applicable. The control process 600 then proceeds to 612.

At 612, the control module 106 identifies a severity level for liquid intrusion inside the battery pack. For example, and as explained above, the control module 106 may identify a severity level based on which one or more of the characteristics caused the one or more flags to be set. In such examples, the severity level identified may be a high severity level corresponding to a severe state of liquid intrusion, a low severity level corresponding to a less severe state of liquid intrusion as compared to the high severity level, and/or intermedial severity levels between the high severity level and the low severity level.

The control process 600 then proceeds to 614, where the control module 106 takes different actions based on the identified severity level. For example, if the severity level is identified as a high severity level (yes at 614), the control process 600 proceeds to 618 where the control module 106 selects one or more urgent remedial actions as explained above. If, however, the severity level is not identified as a high severity level (no at 614), the control process 600 proceeds to 616 where the control module 106 selects one or more non-urgent remedial actions as explained above. The control process 600 then proceeds to 620, where the control module 106 generates one or more control signals for implementing the selected urgent or non-urgent remedial actions, as explained above. The control process 600 then ends as shown in FIG. 6 or may return to another suitable step, such as 602, 606, etc.

In FIG. 7, the control process 700 is similar to the control process 600 of FIG. 6 but includes additional steps. For example, and as shown in FIG. 7, the control process 700 begins at 602 of FIG. 6 and then proceeds to 604, 606, 608, 610 as explained above relative to FIG. 6. The control process 700 then proceeds to 712.

At 712, the control module 106 determines whether any of the flags set at 610 relates to a reduction of isolation resistance, such as a current value of the isolation resistance failing below a defined threshold as explained above. If no, the control process 700 proceeds to 714 where the control module 106 identifies a severity level for liquid intrusion inside the battery pack as a low severity level. The control process 700 then proceeds to 616, 620 of FIG. 6 explained above. However, if yes at 712, the control process 700 proceeds to 716 where the control module 106 identifies a severity level for liquid intrusion inside the battery pack as a high severity level. The control process 700 then proceeds to 618, 620 of FIG. 6 explained above. The control process 700 then ends as shown in FIG. 7 or may return to another suitable step, such as 602, 606, etc.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A system for detecting and remediating liquid intrusion inside a battery pack of a vehicle, the system comprising:
a battery pack including a plurality of battery cells;
a sensor configured to sense a midpack voltage of the battery pack; and
a control module in communication with the one or more sensors, the control module configured to:
determine an isolation resistance of the battery pack based on the midpack voltage;
monitor characteristics associated with the battery pack and indicative of liquid intrusion inside the battery pack, the characteristics including a current value of the isolation resistance, a behavior of the midpack voltage over time, and a behavior of the isolation resistance over time;
set one or more flags based on the monitored characteristics;
identify a severity level of a plurality of severity levels for liquid intrusion inside the battery pack based on which one or more of the characteristics caused the one or more flags to be set; and
select at least one remedial action of a plurality of remedial actions in response to the identified severity level for remediating liquid intrusion inside the battery pack.

2. The system of claim 1, wherein the control module is configured to generate a control signal for implementing the at least one selected remedial action.

3. The system of claim 1, wherein the plurality of severity levels include a first severity level corresponding to a severe state of liquid intrusion and a second severity level corresponding to a less severe state of liquid intrusion as compared to the first severity level.

4. The system of claim 3, wherein the control module is configured to identify the first severity level for liquid intrusion inside the battery pack when the current value of the isolation resistance is less than a defined threshold.

5. The system of claim 4, wherein:
the plurality of remedial actions include a set of urgent remedial actions and a set of non-urgent remedial actions; and
the control module is configured to select at least one of the urgent remedial actions in response to identifying the first severity level.

6. The system of claim 5, wherein the set of urgent remedial actions include changing a charge control setting for the battery pack, changing a chiller control setting for the vehicle, changing a power limit setting for the vehicle, changing a coolant pump control setting, setting a diagnostic trouble code (DTC), and providing an emergency driver notification.

7. The system of claim 3, wherein the control module is configured to identify the second severity level for liquid intrusion inside the battery pack based on a change in the midpack voltage over time and a first threshold or a change in the isolation resistance over time and a second threshold.

8. The system of claim 7, wherein:
the plurality of remedial actions include a set of urgent remedial actions and a set of non-urgent remedial actions;
the control module is configured to select at least one of the non-urgent remedial actions in response to identifying the second severity level; and
the set of non-urgent remedial actions include changing a state-of-charge limit for the battery pack, changing a power limit setting for the vehicle, setting a diagnostic trouble code (DTC), and providing a driver notification.

9. The system of claim 1, wherein:
the plurality of severity levels include a first severity level corresponding to a severe state of liquid intrusion and a second severity level corresponding to a less severe state of liquid intrusion as compared to the first severity level;
the one or more flags include at least a first flag set based on the current value of the isolation resistance and a second flag set based on the behavior of the midpack voltage over time or the behavior of the isolation resistance over time; and
the identified severity level is the first severity level.

10. The system of claim 1, wherein:
the plurality of severity levels include a first severity level corresponding to a severe state of liquid intrusion and a second severity level corresponding to a less severe state of liquid intrusion as compared to the first severity level;
the one or more flags include at least a first flag set based on the behavior of the midpack voltage over time and a second flag set based on the behavior of the isolation resistance over time; and
the identified severity level is the second severity level.

11. A method for detecting and remediating liquid intrusion inside a battery pack of a vehicle, the method comprising:
receiving, from a voltage sensor, a midpack voltage of the battery pack;
determining an isolation resistance of the battery pack based on the midpack voltage;
monitoring characteristics associated with the battery pack and indicative of liquid intrusion inside the battery pack, the characteristics including a current value of the isolation resistance, a behavior of the midpack voltage over time, and a behavior of the isolation resistance over time;
setting one or more flags based on the monitored characteristics;
identifying a severity level of a plurality of severity levels for liquid intrusion inside the battery pack based on which one or more of the characteristics caused the one or more flags to be set; and
selecting at least one remedial action of a plurality of remedial actions in response to the identified severity level for remediating liquid intrusion inside the battery pack.

12. The method of claim 11, further comprising generating a control signal for implementing the at least one selected remedial action.

13. The method of claim 12, wherein:
the plurality of severity levels include a first severity level corresponding to a severe state of liquid intrusion and a second severity level corresponding to a less severe state of liquid intrusion as compared to the first severity level;
the one or more flags include at least a first flag set based on the current value of the isolation resistance and a second flag set based on the behavior of the midpack voltage over time or the behavior of the isolation resistance over time; and
identifying the severity level for liquid intrusion inside the battery pack includes identifying the first severity level.

14. The method of claim 12, wherein:
the plurality of severity levels include a first severity level corresponding to a severe state of liquid intrusion and a second severity level corresponding to a less severe state of liquid intrusion as compared to the first severity level;
the one or more flags include at least a first flag set based on the behavior of the midpack voltage over time and a second flag set based on the behavior of the isolation resistance over time; and
identifying the severity level for liquid intrusion inside the battery pack includes identifying the second severity level.

15. The method of claim 11, wherein:
the plurality of severity levels include a first severity level corresponding to a severe state of liquid intrusion and a second severity level corresponding to a less severe state of liquid intrusion as compared to the first severity level; and
the plurality of remedial actions include a set of urgent remedial actions and a set of non-urgent remedial actions.

16. The method of claim 15, wherein:
identifying the severity level for liquid intrusion inside the battery pack includes identifying the first severity level when the current value of the isolation resistance is less than a defined threshold;
selecting the at least one remedial action includes selecting at least one of the urgent remedial actions in response to identifying the first severity level; and
the set of urgent remedial actions include changing a charge control setting for the battery pack, changing a chiller control setting for the vehicle, changing a power limit setting for the vehicle, changing a coolant pump control setting, setting a diagnostic trouble code (DTC), and providing an emergency driver notification.

17. The method of claim 15, wherein:
identifying the severity level for liquid intrusion inside the battery pack includes identifying the second severity level based on a change in the midpack voltage over time and a first threshold or a change in the isolation resistance over time and a second threshold; and
selecting the at least one remedial action includes selecting at least one of the non-urgent remedial actions in response to identifying the second severity level.

18. The method of claim 17, wherein the set of non-urgent remedial actions include changing a state-of-charge limit for the battery pack, changing a power limit setting for the vehicle, setting a diagnostic trouble code (DTC), and providing a driver notification.

19. A non-transitory computer readable medium including instructions that, when executed by a control module, are configured to detect and remediate liquid intrusion inside a battery pack of a vehicle by:
determining an isolation resistance of the battery pack based on a sensed midpack voltage;
monitoring characteristics associated with the battery pack and indicative of liquid intrusion inside the battery pack, the characteristics including a current value of the isolation resistance, a behavior of the midpack voltage over time, and a behavior of the isolation resistance over time;
setting one or more flags based on the monitored characteristics;
identifying a severity level of a plurality of severity levels for liquid intrusion inside the battery pack based on which one or more of the characteristics caused the one or more flags to be set; and
selecting at least one remedial action of a plurality of remedial actions in response to the identified severity level for remediating liquid intrusion inside the battery pack.

20. The non-transitory computer readable medium of claim 19, further comprising instructions for generating a control signal for implementing the at least one selected remedial action.
